(19) United States
(12) Patent Application Publication
(10) Pub. No.: US 2014/0339665 A1
(43) Pub. Date: Nov. 20, 2014

(54) IMAGE SENSOR

(71) Applicant: Fujifilm Corporation, Tokyo (JP)

(72) Inventor: Takeharu TANI, Ashigarakami-gun (JP)

(21) Appl. No.: 14/446,711

(22) Filed: Jul. 30, 2014

Related U.S. Application Data
(63) Continuation of application No. PCT/JP2013/000324, filed on Jan. 23, 2013.

(30) Foreign Application Priority Data
Jan. 31, 2012 (JP) 2012-017507

(51) Int. Cl. G01J 1/02; H01L 27/146; G01J 1/04

(52) U.S. Cl. CPC G01J 1/0295; G01J 1/0492; H01L 27/14621
USPC 257/432

(57) ABSTRACT

An image sensor having a plurality of photoelectric conversion elements that receive light and convert the light to electric charges, color filter layers having different spectral characteristics, each being provided corresponding to each of the photoelectric conversion elements, and a partition wall having a lower refractive index than that of the color filter layers provided at the boundary of each color filter layer. The image sensor is formed such that a space of the partition wall on the light exit side is narrower than a space of the partition wall on the light incident side.

### CROSS-REFERENCE TO RELATED APPLICATIONS

This application is a Continuation of PCT International Application No. PCT/JP2013/000324 filed on Jan. 23, 2013, which claims priority under 35 U.S.C. §119 (a) to Japanese Patent Application No. 2012-017507 filed on Jan. 31, 2012. Each of the above application(s) is hereby expressly incorporated by reference, in its entirety, into the present application.

### BACKGROUND OF THE INVENTION

1. Technical Field

The present invention relates to an image sensor which includes a plurality of photoelectric conversion elements, each having a color filter with a partition wall at the boundary thereof.

2. Background Art

Heretofore, various types of image sensors, such as CCD, CMOS, and the like, have been proposed in which a plurality of photoelectric conversion elements that convert light to an electric charge is disposed.

As such image sensors, those provided with color filters are known. For example, an image sensor provided with a primary color filter formed of a combination of red (R), blue (B), and green (G), an image sensor provided with a complementary color filter formed of a combination of cyan (C), magenta (M), yellow (Y), and green (G), and the like are known.

Here, light incident on an image sensor provided with a color filter like that described above is not necessarily perpendicular to the light receiving surface of the image sensor and parallel to each other. Therefore, there may be a case in which light incident from an oblique direction with respect to the light receiving surface transmits through one color filter, and then incident on an adjacent color filter and photoelectric conversion element, thereby causing a problem of color mixing.

In order to solve the aforementioned problem of color mixing, for example, Japanese Unexamined Patent Publication No. 2006-295125, Japanese Unexamined Patent Publication No. 2010-232537, Japanese Unexamined Patent Publication No. 3(1991)-282403, and Japanese Unexamined Patent Publication No. 2009-111225 propose to provide at the boundary of each color filter provided corresponding to each photoelectric conversion element a partition wall formed of a material having a lower refractive index than that of the color filter.

### DISCLOSURE OF THE INVENTION

But, even if the partition wall is provided at the boundary of each color filter as described above, light incident on the partition wall does not directly pass through the partition wall portion and an action that gradually draws the light into a material having a higher refractive index is exerted. For example, this action may cause a problem that the light incident on a blue (B) filter is incident on a green (G) filter via the partition wall and the incident efficiency of the blue light on the photoelectric conversion element is reduced, and light incident on a green (G) filter is incident on a red (R) filter via the partition wall and the incident efficiency of the green light on the photoelectric conversion element is reduced. This problem may occur when the space of the partition wall is relatively small and appears significantly, in particular, when the space of the partition wall is about the wavelength of the incident light or less.

On the other hand, if the space of the partition wall is too wide, the light transmitted through the partition wall is incident on photoelectric conversion elements without transmitting through each color filter, thereby causing the problem of color mixing.

In view of the aforementioned problems, it is an object of the present invention to provide an image sensor capable of improving incident efficiency of light transmitted through each color filter on the photoelectric conversion element and inhibiting color mixing.

An image sensor of the present invention includes a plurality of photoelectric conversion elements that receive light and convert the light to electric charges, color filters having different spectral characteristics, each being provided corresponding to each of the photoelectric conversion elements, and a partition wall having a lower refractive index than that of the color filters provided at the boundary of each color filter, wherein the partition wall is formed so as to be narrower in space on the exit side of the light than on the incident side of the light.

In the image sensor of the present invention described above, the partition wall may be formed such that the space becomes narrower in a tapered manner from the incident side to the exit side of the light.

Further, the partition wall may be formed in a tapered shape on the incident side of the light and in a pillar shape having a constant space on the exit side of the light.

Still further, a portion of the partition wall having a widest space may be 0.3 μm or more and a portion of the partition wall having a narrowest space may be 0.2 μm or less.

Further, the length of a portion of the partition wall in which the space of the partition wall is 0.2 μm or less may be 0.2 μm to 0.5 μm.

Still further, the difference in refractive index between the color filters disposed adjacently may be 0.1 or more for any wavelength within a use wavelength range of the image sensor.

Further, the color filters may be a red filter, a blue filter, and a green filter.

Still further, the size of the image sensor may be 1.8 μm or less.

According to the image sensor of the present invention, which is an image sensor provided with a partition wall at the boundaries of color filters having different spectral characteristics, the partition wall is formed so as to be narrower in space on the exit side of the light than on the incident side of the light. This may inhibit the action that draws light transmitted through the partition wall into an adjacent color filter at an area of the partition wall having a wide space on the light incident side, so that the incident efficiency of light transmitted through each color filter on the photoelectric conversion element may be improved. In the meantime, the spectral characteristics based on the original absorption of the color filters may be maintained at an area of the partition wall having a narrow space on the light incident side, so that color mixing may be inhibited.

### BRIEF DESCRIPTION OF DRAWINGS

FIG. 1 is a cross-sectional view of an embodiment of the image sensor of the present invention, illustrating a schematic configuration thereof.

FIG. 2 is a top view of the image sensor illustrated in FIG. 1.

FIG. 3 shows refractive index dispersions of the R filter, G filter, and B filter of the image sensor shown in FIG. 1.

FIG. 4 shows a simulation result of light incident efficiency of each color filter in a case in which the partition wall is formed in a tapered shape with a maximum space of the partition wall d1=0.4 μm, a minimum space of the partition wall d2=0.1 μm, and a distance h=0.5 μm in which the space of the partition wall d3=0.2 μm or less.

FIG. 5 illustrates an example partition wall formed in a pillar shape with a constant space.

FIG. 6 shows a simulation result of light incident efficiency of each color filter in a case in which a space of the partition wall shown in FIG. 5 is set to d4=0.1 μm.

FIG. 7 illustrates another example partition wall formed in a pillar shape with a constant space.

FIG. 8 shows a simulation result of light incident efficiency of each color filter in a case in which a space of the partition wall shown in FIG. 7 is set to d5=0.3 μm.

FIG. 9 shows a simulation result of light incident efficiency of each color filter in a case in which the partition wall is formed in a tapered shape with a maximum space of the partition wall d1=0.3 μm, a minimum space of the partition wall d2=0.1 μm, and a distance h=0.4 μm in which a space of the partition wall d3=0.2 μm or less.

FIG. 10 shows a simulation result of light incident efficiency of each color filter in a case in which the partition wall is formed in a tapered shape with a maximum space of the partition wall d1=0.4 μm, a minimum space of the partition wall d2=0.2 μm, and a distance h=0.2 μm in which a space of the partition wall d3=0.2 μm or less.

FIG. 11 illustrates an embodiment in which the present invention is applied to a back-illuminated image sensor.

### BEST MODE FOR CARRYING OUT THE INVENTION

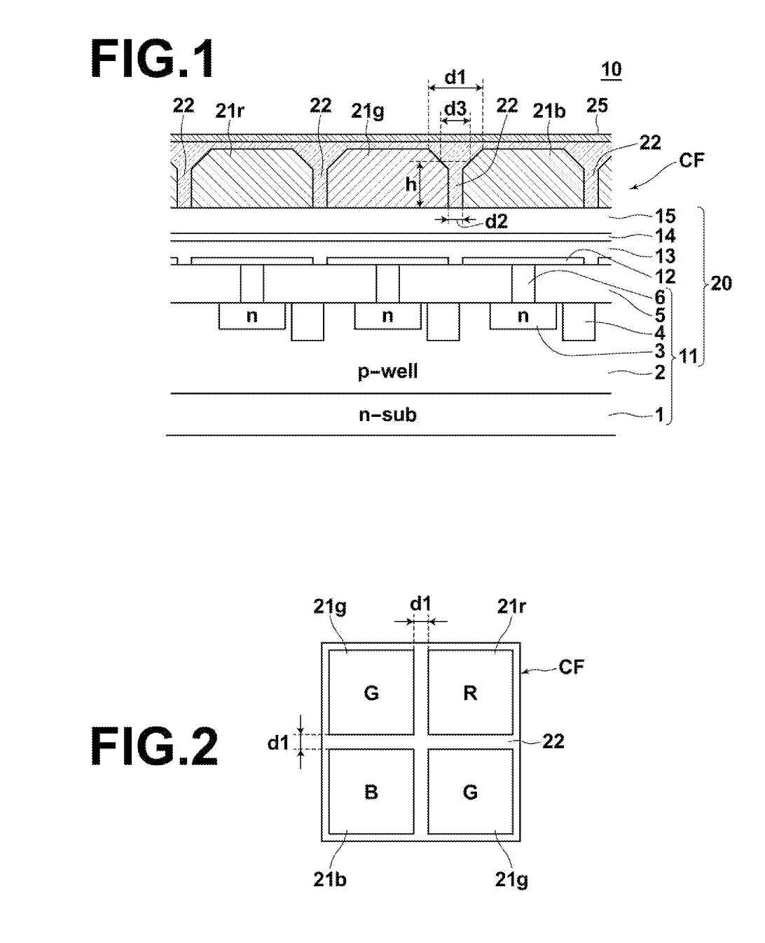

Hereinafter, an embodiment of the image sensor of the present invention will be described in detail with reference to the accompanying drawings. FIG. 1 is a cross-sectional view of the image sensor of the present embodiment, illustrating a schematic configuration thereof.

As illustrated in FIG. 1, the image sensor 10 of the present embodiment includes a semiconductor circuit board 11, a plurality of pixel electrodes 12 formed on the semiconductor circuit board 11 in a two-dimensional array, a photoelectric conversion layer 13 formed continuously on the plurality of pixel electrodes 12 with an organic material, a common electrode (upper electrode) 14 which is the counter electrode opposite to the plurality of pixel electrodes 12 formed on the photoelectric conversion layer 13 as a single layer. Further, a transparent insulating layer 15 is formed on the upper electrode 14, and from the semiconductor circuit board 11 to the insulating layer 15 are collectively referred to as an image sensor substrate 20. A color filter layer CF which includes a red (R) color filter 21r, a green (G) color filter 21g, and a blue (B) color filter 21b, and a transparent partition wall 22 that separates and isolates each of the color filters 21r, 21g, 21b of the respective colors is provided on the insulating layer 15 of the image sensor substrate 20, and a low-reflection layer 25 is further provided on the color filter layer CF. Note that one photoelectric conversion element is formed by one pixel electrode 12, and the photoelectric conversion layer 13 and the upper electrode 14 located above the pixel electrode 12. Preferably, the size of the photoelectric conversion element is 1.8 μm or less.

Hereinafter, each constituent element of the image sensor 10 will be described in detail.

The semiconductor circuit board 11 includes an n-type silicon substrate 1 (hereinafter, simply referred to as “substrate 1”) with a p-type well region 2 formed thereon and a plurality of n-type impurity diffusion regions 3 is formed in the well region 2. The impurity diffusion regions 3 are formed in a two-dimensional array corresponding to the pixel electrodes 12 formed on the circuit board 11. Further, signal reading sections 4 are provided adjacent to the impurity diffusion regions 3 in the surface of the well region 2 to output signals corresponding to the electric charges accumulated in the impurity diffusion regions.

The signal reading section 4 is a circuit that converts electric charges accumulated in the impurity diffusion region 3 to a voltage signal and outputs the voltage signal, and may be formed, for example, of a known CCD or CMOS circuit.

Further an insulating layer 5 is layered on the surface of the well region 2 of the substrate 1. A plurality of pixel electrodes 12, each having a substantially square shape in planar view, is arranged and formed on the insulating layer 5 at a predetermined interval. Each pixel electrode 12 is electrically connected to the impurity diffusion region 3 of the substrate 1 via a connection section 6 formed with a conductive material so as to penetrate the insulating layer 5.

When light is incident on the photoelectric conversion layer 13, the image sensor 10 causes a voltage supply section (not shown) to apply a bias voltage between the pixel electrode 12 and the upper electrode 14 such that, for example, of the electric charges (holes and electrons) generated in the photoelectric conversion layer 13, the holes are moved to the upper electrode 14 while the electrons are moved to the pixel electrode 12. In this case, the upper electrode 14 is used as the hole collecting electrode and the pixel electrode 12 is used as the electron collection electrode. Conversely, a configuration may be adopted in which electrons are moved to the upper electrode 14 while the holes are moved to the pixel electrode 12.

The materials of the upper electrode 14 and the pixel electrode 12 are selected by considering the adhesion to the photoelectric conversion layer 13, electron affinity, ionization potential, stability, and the like.

Various types of methods are used for preparing the upper electrode 14 and the pixel electrode 12 depending on the material used. In the case of ITO, for example, electron beam method, sputtering, resistance heating evaporation method, chemical reaction method (sol-gel method and the like), coating of indium tin oxide dispersion, and the like, are used to form a film. In the case of ITO, UV ozone treatment, plasma treatment, and the like may be performed.

The upper electrode 14 is formed of a transparent conductive material as it is necessary to allow light to incident on the photoelectric conversion layer 13. Here, a transparent electrode material having a transmission factor of about 80% or more for a wavelength, for example, in a visible light range from about 420 nm to about 660 nm is preferable.

Specific materials of the upper electrode 14 include, for example, conductive metal oxides, such as tin oxide, zinc oxide, indium tin oxide (ITO), metals, such as gold, silver, chrome, nickel, and the like, mixtures or layered bodies of these metals and conductive metal oxides, inorganic conductive materials, such as copper iodide, copper sulfide, and the like, organic conductive materials, such as polyaniline, polythiophene, polypyrrole, and the like, silicon compounds and layered bodies of these compounds and ITO, and the like, in which the conductive metal oxides are preferable, and ITO, ZnO, InO are particularly preferable in view of the productivity, high conductivity, transparency, and the like.

The pixel electrode 12 may be made of any conductive material and is not necessarily transparent. If it is necessary to transmit light to the substrate 1 located under the pixel electrode 12, however, the pixel electrode 12 also needs to be formed of a transparent electrode material. In this case, the use of ITO is preferable as the transparent electrode material of the pixel electrode 12, as in the upper electrode 14.

The photoelectric conversion layer 13 is formed of an organic material having a photoelectric conversion function to convert light to an electric charge or the like. As for the organic materials, various organic semiconductor materials, such as those used as the photosensitive materials of electrophotography may be used. Among them, a material having a quinacridone skeleton and an organic material having phthalocyanine skeleton are particularly preferable in view of high photoelectric conversion performance, excellent color separation in spectroscopy, high durability against long exposer of light, suitability for vacuum deposition, and the like.

Further, the organic material for forming the photoelectric conversion layer 13 preferably includes at least one of p-type semiconductor and n-type semiconductor. For example, as the p-type organic semiconductor and the n-type organic semiconductor, it is preferable to use any of quinacridone derivatives, naphthalene derivatives, anthracene derivatives, phenanthrene derivatives, tetracene derivatives, pyrene derivatives, perylene derivatives, and fluoranthene derivatives.

The use of an organic material as the material of the photoelectric conversion layer 13 may result in a higher light absorption coefficient in comparison with a structure in which a photodiode formed on a silicon substrate or the like is used as the photoelectric conversion section. Consequently, the light incident on the photoelectric conversion layer 13 is likely to be absorbed, which causes obliquely incident light to be less likely to leak into an adjacent photoelectric conversion element, thereby allowing improvement of transmission efficiency and inhibition of cross-talk.

The insulating layer 15 may be formed of Al₂O₃, SiO₂, SiN, or a mixed film of these.

The color filter layer CF includes a plurality of color filters having different spectral characteristics, and more specifically, it includes, in the present embodiment, a red (R) color filter (hereinafter, R filter) 21r, a green (G) color filter (hereinafter, G filter) 21g, and a blue (B) color filter (hereinafter, B filter) 21b as described above.

Each of the R filter 21r, G filter 21g, and B filter 21b is formed of an organic material having a pigment or a dye. As illustrated in FIG. 1, any one of the filters is disposed for each photoelectric conversion element and they are arranged in a color pattern, such as a Bayer arrangement, as shown in FIG. 2. FIG. 2 is a top view of the color filter layer CF illustrated in FIG. 1.

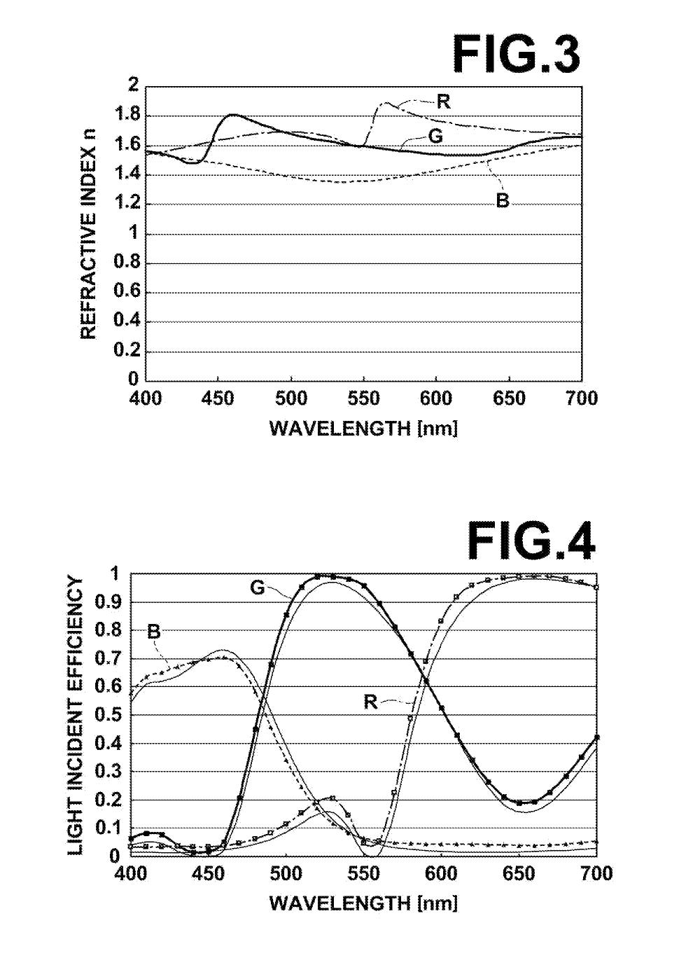

The refractive indices of the R filter 21r, G filter 21g, and B filter 21b differ depending on the color and the wavelength of the incident light, but each of the R filter 21r, G filter 21g, and B filter 21b has a refractive index in a range of 1.3 to 1.9 with a use wavelength range of the image sensor 10 (at least wavelengths in a visible light region of 400 nm to 700 nm). FIG. 3 shows a refractive index dispersion of each of the R filter 21r, G filter 21g, and B filter 21b used in the present embodiment.

Further, in the present embodiment, an R filter 21r and a G filter 21g are disposed adjacently and a G filter 21g and a B filter are disposed adjacently. For the adjacently disposed color filters, those having a difference of 0.1 or more in refractive index for any wavelength in the wavelength range used by the image sensor 10 (at least wavelengths in a visible light region of 400 nm to 700 nm) are used.

The thickness of each of the color filters 21r, 21g, 21b is within the range of 0.3 to 1.0 μm.

As illustrated in FIG. 1, the color filters 21r, 21g, 21b of the present embodiment have an upward convex shape in the cross-sectional structure.

Then a partition wall 22 made of a transparent material having a lower refractive index than that of a material of the color filters 21r, 21g, 21b is provided at the boundary of each of the color filters 21r, 21g, 21b.

The partition wall 22 is to actively collect light transmitted through the color filters 21r, 21g, 21b into the photoelectric conversion layer 13 as described above, whereby reduction in transmission factor and increase in cross-talk may be inhibited.

Here, as described above, even if a partition wall is provided at the boundary of each color filter, light incident on the partition wall does not directly pass through the partition wall portion and an action that gradually draws the light into a color filter formed of a material having a higher refractive index is exerted. For example, this action may cause a problem that the light incident on a B filter is incident on a G filter via the partition wall and the incident efficiency of blue light on the photoelectric conversion element is reduced, and light incident on a G green filter is incident on a R filter via the partition wall and the incident efficiency of the green light on the photoelectric conversion element is reduced. This problem appears significantly, in particular, when the space of the partition wall is about the wavelength of the incident light or less.

On the other hand, if the space of the partition wall is too wide, the light transmitted through the partition wall is incident on the photoelectric conversion elements without transmitting through each color filter, thereby causing the problem of color mixing.

Consequently, a partition wall 22 that does not cause reduction in the light incident efficiency and color mixing is formed in the present embodiment. That is, as illustrated in FIG. 1, the partition wall 22 is formed such that a space d2 of the partition wall 22 on the light exit side is smaller than a space d1 of the partition wall 22 on the light incident side. In the structure shown in FIG. 1, each partition wall 22 provided at the boundary of each of the color filters 21r, 21g, 21b, is integrated by a planar layer on the light incident side, but the space of the partition wall 22 as used herein refers to a space of the partition wall at the boundary portion of each of the color filters 21r, 21g, 21b. Further, each partition wall 22 is not necessarily formed integrally as in FIG. 1 and may be formed in a separate structure.

More specifically, the partition wall 22 in the present embodiment is formed in a tapered shape on the light incident side such that the space is gradually reduced toward the light exit side and in a pillar shape on the light exit side such that the space becomes constant, as illustrated in FIG. 1. In this way, by forming the partition wall 22 in a tapered shape on the light incident side, the aforementioned light incident on an adjacent color filter may be inhibited and light incident efficiency may be improved. Further, by reducing the space of the partition wall 22 on the light exit side, the light reaching the photoelectric conversion elements without passing through the color filters may be inhibited and color mixing may be prevented.

FIG. 4 shows a simulation result of light incident efficiency of each of the color filters 21r, 21g, 21b in a case in which the partition wall 22 is formed in a tapered shape as shown in FIG. 1 with a maximum space of the partition wall d1=0.4 μm, a minimum space of the partition wall d2=0.1 μm, and a distance h=0.5 μm in which a space of the partition wall d3=0.2 μm or less. The “light incident efficiency” as used herein refers to a ratio of the light transmitted through a color filter and reached the photoelectric conversion element to the light incident on the color filter. The curves depicted by narrow solid lines in FIG. 4 represent ideal spectral transmission factors of the respective color filters of RGB.

As shown in FIG. 4, it is known that the light incident efficiency of each of the color filters 21r, 21g, 21b is close enough to the ideal spectral transmission factor of each of the color filters of RGB.

In the meantime, a simulation result of light incident efficiency of each of the color filters R, G, B in a case in which the partition wall is formed in a pillar shape with a constant space as in the past, instead of forming the partition wall 22 in a tapered shape as in the present embodiment, is shown as a comparative example.

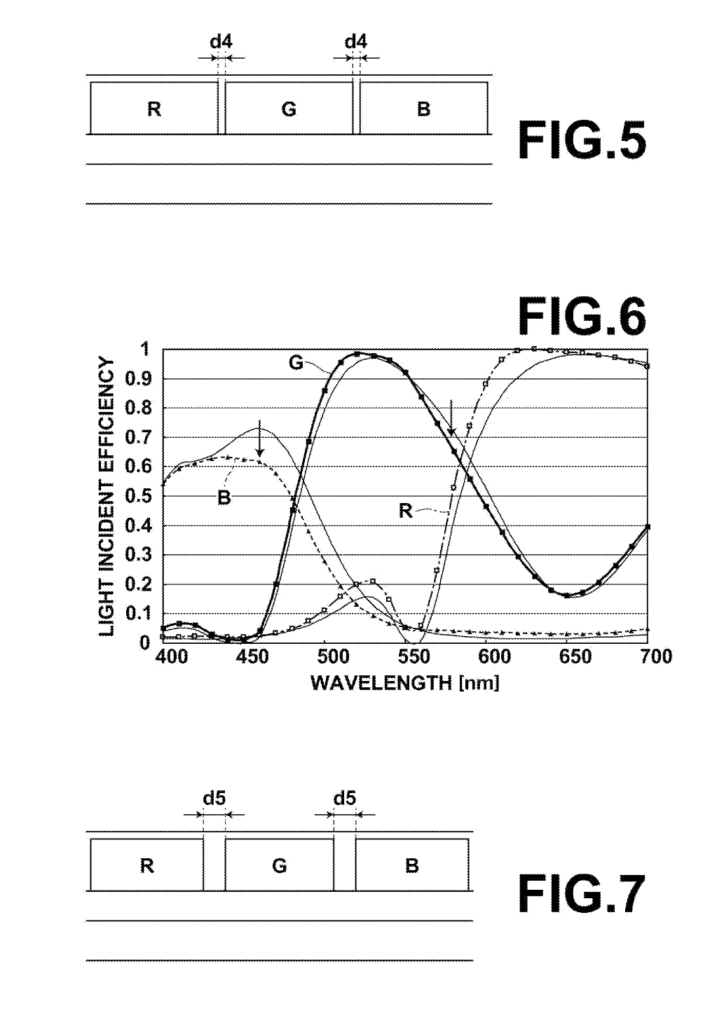

FIG. 6 shows a simulation result of light incident efficiency of each of the color filters R, G, B in a case in which the partition wall is formed in a pillar shape with a constant space d4=0.1 μm, as shown in FIG. 5. As shown in FIG. 6, if the space of the partition wall is set narrow and constant, it is known that the light incident on a B filter is incident on a G filter via the partition wall and the light incident efficiency of B filter is reduced, and light incident on a G green filter is incident on a R filter via the partition wall and the light incident efficiency of the G filter is reduced, as described above. Note that, in FIG. 6, portions where the light incident efficiency is reduced are indicated by arrows.

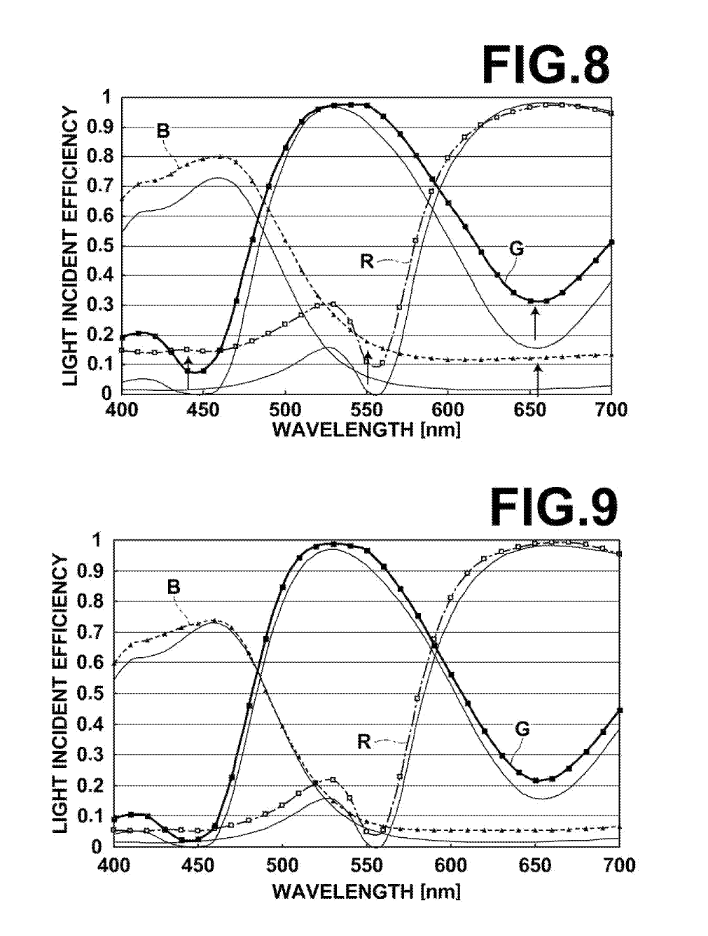

FIG. 8 shows a simulation result of light incident efficiency of each of the color filters R, G, B in a case in which the partition wall is formed in a pillar shape with a constant space d5=0.3 μm, as shown in FIG. 7. As shown in FIG. 8, if the space of the partition wall is set wide and constant, the amount of light that reaches the photoelectric conversion elements without passing through the color filters is increased so that the color separation by each color filter cannot be performed properly and color mixing is aggravated. Note that, in FIG. 8, portions where the color mixing is aggravated are indicated by arrows.

FIG. 9 shows a simulation result of light incident efficiency in a case in which the partition wall 22 is formed in a tapered shape as in FIG. 1 with different conditions from those of the simulation result of light incident efficiency shown in FIG. 4 in the maximum space of the partition wall 22 and the distance h in which the space of the partition wall d3=0.2 μm or less. More specifically, it is a simulation result of light incident efficiency of each of color filters of 21r, 21g, 21b with a maximum space of the partition wall 22 d1=0.3 μm and a distance h=0.4 μm in which the space of the partition wall 22 d3=0.2 μm or less. As shown in FIG. 9, it is known that the reduction in the light incident efficiency and color mixing are inhibited in comparison with the simulation results of the comparative examples of FIGS. 6 and 8.

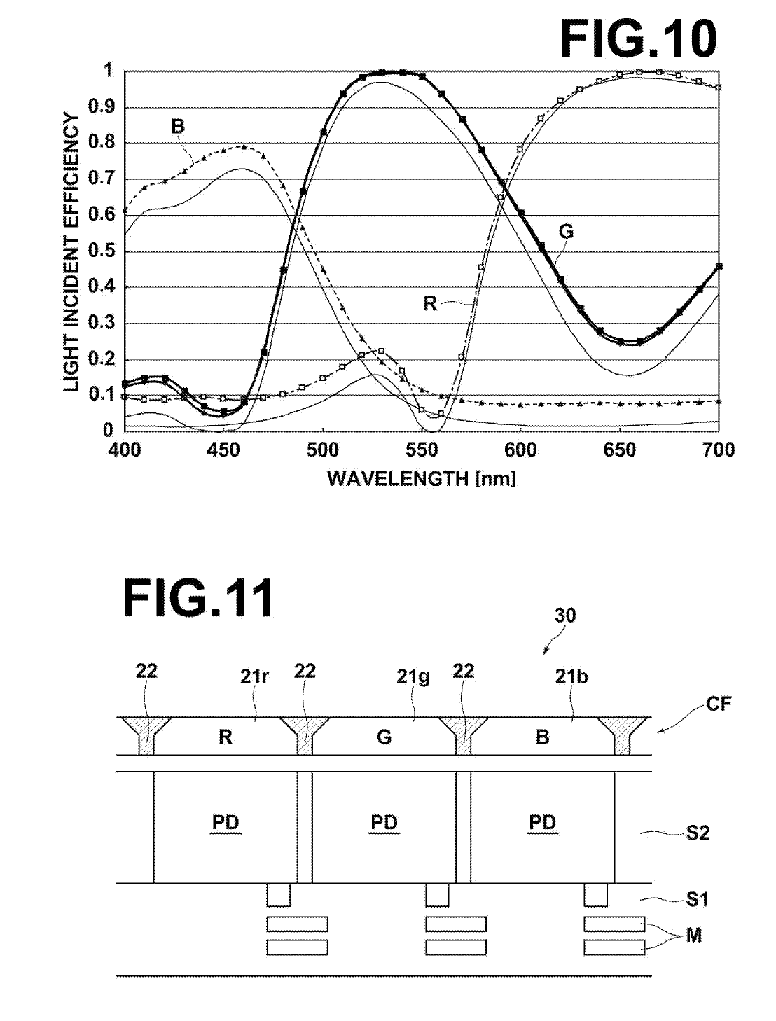

FIG. 10 shows a simulation result of light incident efficiency in a case in which the partition wall 22 is formed in a tapered shape as in FIG. 1 with different conditions from those of the simulation result of light incident efficiency shown in FIG. 4 in the minimum space of the partition wall 22 and the distance h in which the space of the partition wall d3=0.2 μm or less. More specifically, it is a simulation result of light incident efficiency of each of color filters of 21r, 21g, 21b with a minimum space of the partition wall 22 d2=0.2 μm and a distance h=0.2 μm in which the space of the partition wall 22 d3=0.2 μm or less. As shown in FIG. 10, it is known that the reduction in the light incident efficiency and color mixing are inhibited in comparison with the simulation results of the comparative examples of FIGS. 6 and 8.

From the simulation results of the embodiments of the present invention shown in FIGS. 4, 9, and 10, and the simulation results of the comparative examples shown in FIGS. 6 and 8, it is known that the maximum space d1 of the partition wall 22 is preferably 0.3 μm or more and the minimum space d2 is preferably 0.2 μm or less. Note that the maximum value of the maximum space d1 of the partition wall 22 corresponds to the pixel size.

Further, it is known that the distance h in which the space of the partition wall 22 d3=0.2 μm or less is preferably 0.2 μm to 0.5 μm.

In the embodiment described above, the partition wall 22 is formed of a transparent material having a lower refractive index than that of a material of the color filters 21r, 21g, 21b. But, as the refractive index of air is almost 1 which is substantially lower than that of a material of the color filters 21r, 21g, 21b, the partition wall 22 portion may be air, that is, nothing may be provided.

The color filter layer CF of the embodiment described above may also be applied to a back-illuminated image sensor. FIG. 11 illustrates a schematic structure of a back-illuminated image sensor 30 to which the color filter layer CF of the embodiment described above is applied. The image sensor 30 includes a substrate S2, such as silicon or the like, in which silicon photodiodes PD are formed and the silicon photodiodes function as photoelectric conversion elements. The color filter layer CF of the embodiment described above is formed on the surface of the substrate S2 on the light incident side across a planarizing film, an insulating film, and the like.

The image sensor 30 includes a circuit board S1 on the side of the substrate S2 opposite to the side where the color filter layer CF is formed and circuit board S1 includes signal reading circuits for reading out electric charges generated in the silicon photodiodes PD as signals. Note that M in the drawing indicates wiring layers.

In the present embodiment, as the color filter layer, a layer formed of R filters, B filters, and G filters is used, but an identical partition wall configuration to that of the aforementioned embodiment may be used in a case in which a complementary color filter formed of a combination of cyan (C), magenta (M), yellow (Y), and green (G) is used as the color filter layer.

What is claimed is:

1. An image sensor, comprising a plurality of photoelectric conversion elements that receive light and convert the light to electric charges, color filters having different spectral characteristics, each being provided corresponding to each of the photoelectric conversion elements, and a partition wall having a lower refractive index than that of the color filters provided at the boundary of each color filter,
wherein the partition wall is formed so as to be narrower in space on the exit side of the light than on the incident side of the light.

2. The image sensor as claimed in claim 1, wherein the partition wall is formed such that the space becomes narrower in a tapered manner from the incident side to the exit side of the light.

3. The image sensor as claimed in claim 1, wherein the partition wall is formed in a tapered shape on the incident side of the light and in a pillar shape having a constant space on the exit side of the light.

4. The image sensor as claimed in claim 2, wherein the partition wall is formed in a tapered shape on the incident side of the light and in a pillar shape having a constant space on the exit side of the light.

5. The image sensor as claimed in claim 1, wherein a portion of the partition wall having a widest space is 0.3 μm or more and a portion of the partition wall having a narrowest space is 0.2 μm or less.

6. The image sensor as claimed in claim 1, wherein the length of a portion of the partition wall in which the space of the partition wall is 0.2 μm or less is 0.2 μm to 0.5 μm.

7. The image sensor as claimed in claim 1, wherein the difference in refractive index between the color filters disposed adjacently is 0.1 or more for any wavelength within a use wavelength range of the image sensor.

8. The image sensor as claimed in claim 1, wherein the color filters are a red filter, a blue filter, and a green filter.

9. The image sensor as claimed in claim 1, wherein the size of the image sensor is 1.8 μm or less.
